(19) United States
(12) Patent Application Publication
(10) Pub. No.: US 2004/0079947 A1
(43) Pub. Date: Apr. 29, 2004

(54) Light-emitting diode with low resistance layer

(76) Inventors: Wen-How Lan, Taoyuan City (TW); Lung-Chien Chen, Hsin-Chuang City (TW); Fen-Ren Chien, Yung-Ho City (TW)

Correspondence Address: SUPREME PATENT SERVICES, POST OFFICE BOX 2339, SARATOGA, CA, 95070, US

(21) Appl. No.: 10/281,749

(22) Filed: Oct. 26, 2002

(51) Int. Cl. H01L 27/15

(52) U.S. Cl. 257/79

(57) ABSTRACT

The present invention relates to a light-emitting diode structure for increasing the equivalent conductivity of the light-emitting diode and does not necessary to change the thickness of the epitaxy. The structure of the present invention comprises inserting a higher electrical n-type conductivity layer in the epitaxial structure of the light-emitting diode. Furthermore, a tunneling layer made of higher density p-type and n-type materials is inserted in between. Under voltage bias, the current will run through electrode and across the low resistance layer by means of bias/tunneling effect, and finally reach the easily conductive n-type GaN layer, then the current is moving along the p/n junction and arrive at the bottom of the emitting layer. Then after a breakdown/tunneling effect, the current enter into p-type GaN layer and then into the emitting layer for recombination and radiation.

### FIELD OF THE INVENTION

The present invention pertains to semiconductor device, and more specifically to a light-emitting diode device with low hole mobility to reduce the equivalent resistance and suits for the use in wide energy band material such as GaN light-emitting diode device.

### BACKGROUND OF THE INVENTION

The typical optoelectronic device for using epitaxy technique is to produce the following components sequentially on a substrate: a n-type region, a light-emitting region, a p-type region, and two electrode contact region respectively formed on the n-type and p-type region. Because mobility of electron is higher than mobility of hole, and also the effective doped amount of hole is lower than electron, this implies that under the same thickness condition, p-type resistance is larger than n-type resistance. The conventional method for handling the effect is to reduce the thickness of p-type region and to form the p-type region on the uppermost surface of the device in order to reduce the resistance of the device. For the practical application of light-emitting diode, in order to enhance the emitting efficiency, the transparent electrode is a primary choice, normally, a Ni/Au thin film is deposited on the p-type region of GaN light-emitting diode, after executing thermal process to make it transparent thus enhancing the light penetration rate. As concerning the choice of using the conventional transparent electric conductive oxide material, indium tin oxide (ITO) is an appropriate candidate which have an ohmic contact with n-type GaN, but due to the work function constraint, it is incapable to make an excellent ohmic contact, so it may be unable to apply to GaN device directly. Normally, for solving the disadvantages mentioned above, an interlayer is inserted between ITO and p-type GaN to adjust the junction parameters such as work function in order to reduce contact resistance and hence forming an excellent ohmic contact. But the addition of the interlayer may influence the optical transparent ratio and cause a bad effect on their operations. Another disadvantage to be concerned is the stability problem of the device during long-term operation at high temperature.

As a consequence, a p-type downward structure was proposed, but the resistance of such structure is still high. FIG. 1 shows a conventional epitaxial structure of a GaN light-emitting diode, comprising a substrate 101, a GaN buffer layer 103 grown at low temperature, a undoped GaN layer 105, a n-type GaN layer 107, a GaN emitting active layer 109, a p-type GaN layer 111, n-type electrode 113 and p-type transparent electrode 115, and p-type electrode 117.

In the ITO electrode practical application, for the sake of improving the ohmic contact problem of the aforementioned p-type region and the ITO electrode, a p-type downward structure was proposed so that it may solve at least partial problems of the aforementioned disadvantages. As shown in FIG. 2, the structure comprises a substrate 201, a GaN buffer layer 203 grown at low temperature, a undoped GaN layer 205, a p-type GaN layer 207, a GaN emitting active layer 209, a n-type GaN layer 211, a n-type transparent electrode ITO 213, and n-type electrode 215 and p-type electrode 217 formed on the n-type transparent electrode ITO 213 and the p-type GaN layer 207, respectively.

Under this circumstance, although ohmic contact problem of the n-type GaN layer and ITO can be partially solved, but it results a higher resistance in p-type GaN layer 207 and hence restricting the practical usage. Although changing the thickness is another possible way to reduce the associated resistance problem but the improvement is still limited. So how to effectively reduce the resistance of n-type GaN layer 211 becomes a primary concern of the p-type downward structure.

It is a purpose of the present invention to provide a tunneling structure to solve the high resistance problems associated with the light-emitting diode.

It is another purpose of the present invention to provide a tunneling structure to increase the equivalent conductivity of the light-emitting diode.

### SUMMARY OF THE INVENTION

The above problems and others are at least partially solved and the above purposes and others are realized in a structure to increase the equivalent conductivity of the light-emitting diode and do not necessary to change the thickness of a epitaxial layer.

The structure of the present invention comprises inserting a n-type layer with higher electrical conductivity in the epitaxial structure of the light-emitting diode. Furthermore, a tunneling layer made of higher density p-type and n-type materials is inserted in between. Under voltage bias, the current will run through by the bias/tunneling effect to go through electrode, the low resistance layer, and finally reach the n-type layer with higher electrical conductivity, then the current keeps on moving along the p/n junction and arrive at the bottom of the emitting layer. Then, after a breakdown/tunneling effect, the current enter into the p-type layer region and then into the emitting layer for recombination and radiation.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 depicts diagram showing a conventional n-type downward GaN light-emitting diode structure;

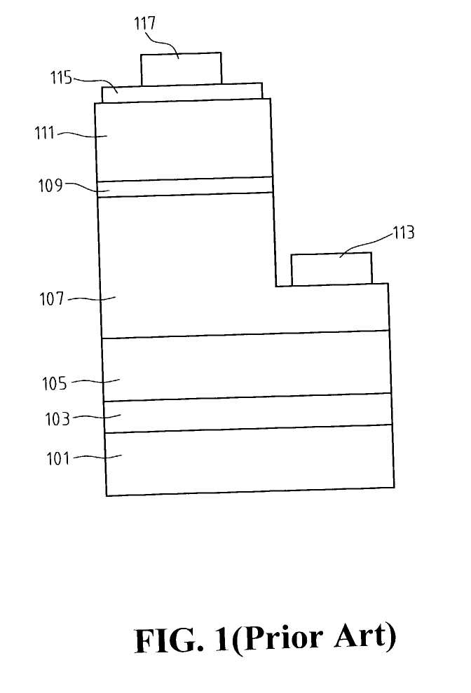

FIG. 2 depicts diagram showing an n-type downward GaN light-emitting diode structure;

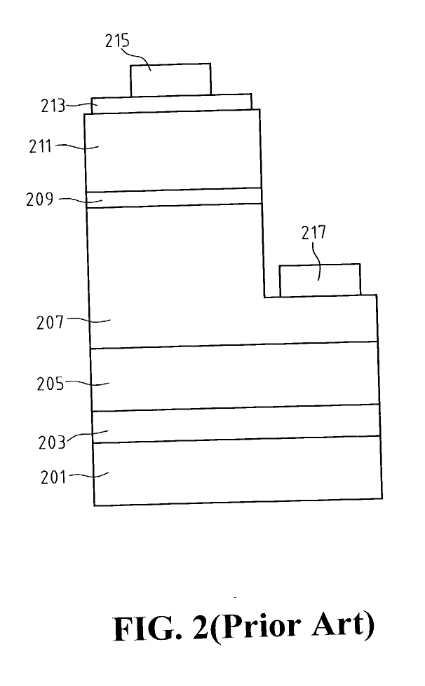

FIG. 3 depicts diagram showing a GaN light-emitting diode epitaxial structure in accordance with the present invention;

FIG. 4 depicts diagram showing a GaN light-emitting diode epitaxial structure of FIG. 2; and

FIG. 5 depicts another prospective view of a GaN light-emitting diode epitaxial structure of FIG. 2.

### DETAILED DESCRIPTION OF THE INVENTION

The preferred embodiment of this invention is shown in the following related figures, The GaN device may be constructed using metal-organic chemical vapor deposition (MOCVD), molecular beam epitaxy (MBE) or any other epitaxy. The n-type doped material of the n-type GaN may be Si, Ge, or any other element with the same function, while the p-type doped material of the p-type GaN may be Mg, Zn, Be, or any other element with the same function.

The function of low resistance layer is by means of carrier tunneling effect or breakdown effect to reduce the electrical resistance. The reality structure is the high density (≧7×10¹⁷/cm³) p/n (junction) or p⁺-GaN/n⁺-GaN(10 to 2000 angstrom) or p/n GaInAlN layer, p/n type GaInAlN super lattice (Inₓ₁Ga_{y1}Al_{(1-x1-y1)}N: MgZnSi/Inₓ₂Ga_{y2}Al_{(1-x2-y2)}N: MgZnSi, wherein 0≦x1, y1≦1, 0≦x2, y2≦1, 0≦x1+y1≦1,0≦x2+y2≦1, the thickness is 10-500/10-500 angstroms, the logarithm value lies between 3 to 100, while the entire thickness is about 60 to 100000 angstroms.

### EMBODIMENT 1

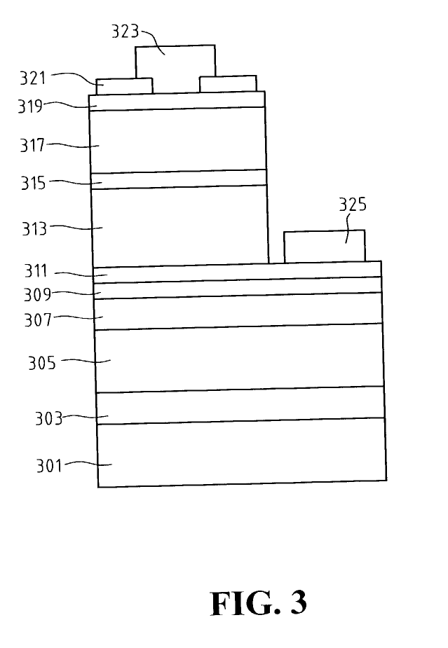

FIG. 3 is a diagram showing the epitaxial structure of GaN light-emitting diode, comprises a substrate 301, the material for the substrate may be Al₂O₃, GaN, SiC, GaAs, Si, Ge, SiGe, and a GaN buffer layer 303 is formed on the surface of the substrate 301, the buffer layer is an amorphous with a thickness of about 50 to 500 angstroms, a undoped GaN layer 305 with a thickness of about 1 to 10 μm, a n-type GaN layer 307 with a thickness of about 0.5 to 2 μm, a low resistance layer 309 with a composition and thickness as mentioned earlier, a heavy doped p-type GaN layer 311 with a thickness of about 500 angstrom to 4 μm, a p-type GaN layer 313, an light-emitting layer 315, a n-type GaN layer 317, a heavy doped n-type GaN layer 319 with a thickness of about 500 angstrom to 2 μm formed on the surface of n-type GaN layer 317 for forming a good ohmic contact. The contact layer may be single layer or multiple layers, made of low energy material such as InₓGa₍₁₋ₓ₎N (0≦x≦1). After the epitaxial process is conducted, further process such as sputtering, lithography, heat treatment, and etching processes are also conducted. an ITO transparent electrode 321 was formed on the surface of the n-type GaN layer 319, a metal contact layer 323 was formed on the surface of the transparent electrode 321, and a p-type contact layer 325 was formed on the top of the p-type GaN layer 311.

### EMBODIMENT 2

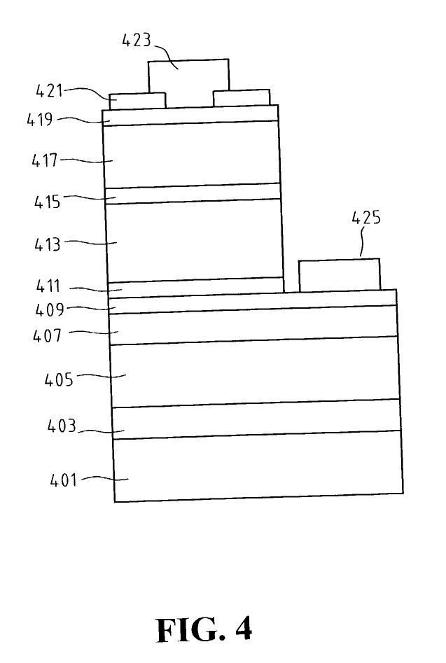

FIG. 4 is another preferred embodiment of the present invention showing the epitaxial structure of GaN light-emitting diode, comprises a substrate 401, the material used for forming the substrate may be Al₂O₃ (sapphire), GaN, SiC, GaAs, Si, Ge, SiGe. A GaN buffer layer 403 made of amorphous with a thickness of about 50 to 500 μm formed on the surface of the substrate 401, a n-type or undoped GaN layer 405 with a thickness of about 1 to 10 μm, a n-type GaN layer 407 with a thickness of about 0.5 to 2 μm, an aforementioned low resistance layer 409 with the structure, composition, and thickness shown as earlier, a heavy doped p-type GaN layer 411 with a thickness of about 500 angstrom to 4 μm, a p-type GaN layer 413, an emitting layer 415, a n-type GaN layer 417, a heavy doped n-type GaN layer 419 with a thickness of about 500 angstrom to 2 μm formed on the surface of n-type GaN layer 417 for forming a good ohmic contact; the contact layer may be a single or multiple layers, made of low energy material such as InₓGa₍₁₋ₓ₎N (0≦x≦1), After the epitaxial process is conducted, further process such as sputtering, lithography, heat treatment, and etching process are also conducted. An ITO transparent electrode 421 was formed on the surface of n-type GaN layer 419, metal contact layer 423 was formed on the surface of the ITO transparent electrode 421, then contact layer 425 was formed on the top of the low resistance layer.

### EMBODIMENT 3

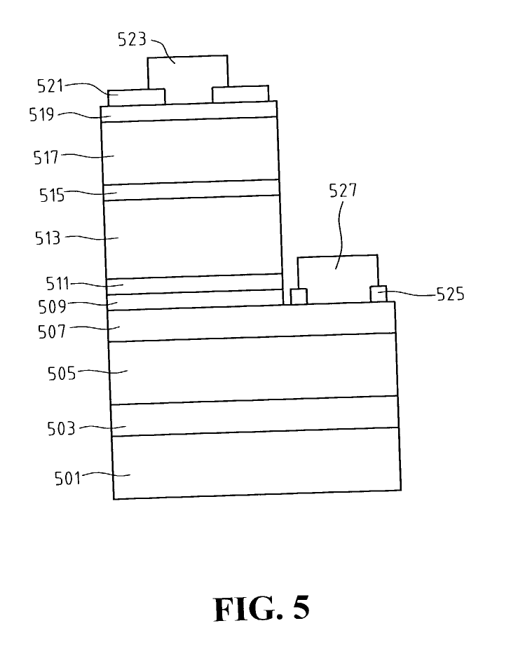

FIG. 5 is further another embodiment of the present invention showing the epitaxy structure of GaN light-emitting diode comprises a substrate 501, the material used for forming the substrate may be Al₂O₃ (sapphire), GaN, SiC, GaAs, Si, Ge, SiGe. A GaN buffer layer 503 made of amorphous with a thickness of about 50 to 500 μm formed on the surface of the substrate 501, a n-type or undoped GaN layer 505 with a thickness of about 1 to 10 μm, a n-type GaN layer 507 with a thickness of about 0.5 to 2 μm, an aforementioned low resistance layer 509 with the structure, composition, and thickness shown as earlier, a heavy doped p-type GaN layer 511 with a thickness of about 500 angstrom to 4 μm, a p-type GaN layer 513, an emitting layer 515, a n-type GaN layer 517, a heavy doped GaN layer 519 with a thickness of about 500 angstrom to 2 μm formed on the surface of n-type GaN layer 517 for forming a good ohmic contact. The contact layer may be a single or multiple layer, made of low energy material such as InₓGa₍₁₋ₓ₎N (0≦x≦1). After the epitaxial process is conducted, further process such as sputtering, lithography, heat treatment, and etching process are also conducted. The ITO transparent electrode 521 and 525 were deposited on the surface of heavy doped n-type GaN layer 519 and the surface of n-type GaN layer 507, respectively, metal contact layer 523 was formed on the surface of the ITO transparent electrode 521, then contact layer 527 was formed on the top of the layer of 525.

While we have shown and described specific embodiments of the present invention, further modifications and improvements will occur to those skilled in the art. We desire it to be understood, therefore, that this invention is not limited to the particular forms shown and we intend in the appended claims to cover all modifications that do not depart from the spirit and scope of this invention.

What is claimed is:

1. A low resistance structure of a light-emitting diode, wherein said structure comprises a low resistance layer positioned in either p-type or n-type region, wherein the carrier may by means of tunneling effect, breakdown effect, or the other effect having the same function to reduce the resistance or working voltage of said structure.

2. The structure of claim 1, wherein said low resistance layer is a higher density p/n junction.

3. The structure of claim 2, wherein said higher density p/n junction having a density of 7×10¹⁷/cm³.

4. The structure of claim 2, wherein said p/n junction having a thickness of about 10 angstrom to 2000 angstrom.

5. The structure of claim 1, said low resistance layer is a p/n junction GaInAlN super lattice structure (Inₓ₁Ga_{y1}Al_{(1-x1-y1)}N: MgZnSi/Inₓ₂Ga_{y2}Al_{(1-x2-y2)}N: MgZnSi (0≦x1, y1≦1, 0≦x2, y2≦1, 0≦x1+y1≦1, 0≦x2+y2≦1) the thickness is about 10-500/10-500 angstroms, the logarithm value lies in the range between 3 to 100, the entire thickness is about 210 to 100000 angstroms.

6. The structure of claim 1, further comprises a bottom electrode on said p-type GaN layer, said low resistance layer, or said n-type GaN layer.
